(19) United States
(12) Patent Application Publication
(10) Pub. No.: US 2006/0091458 A1
(43) Pub. Date: May 4, 2006

(54) Nonvolatile memory device and method of manufacturing the same

(75) Inventors: Ki-chul Kim, Suwon-si (KR); Geum-jong Bae, Incheon Metropolitan City (KR); In-wook Cho, Yongin-si (KR); Byoung-jin Lee, Seoul (KR); Byou-ree Lim, Yongin-si (KR)

Correspondence Address: MILLS & ONELLO LLP, ELEVEN BEACON STREET, SUITE 605, BOSTON, MA, 02108, US

(73) Assignee: Samsung Electronics Co., Ltd.

(21) Appl. No.: 11/265,720

(22) Filed: Nov. 2, 2005

(30) Foreign Application Priority Data
Nov. 3, 2004 (KR) 10-2004-0088941

(51) Int. Cl. H01L 29/94

(52) U.S. Cl. 257/330

(57) ABSTRACT

Provided are a nonvolatile memory device that has enhanced endurance and can accurately read stored data, and a method of manufacturing the same. The nonvolatile memory device includes a trench formed in a semiconductor substrate, a gate electrode formed in the trench, a gate electrode insulating layer interposed between the gate electrode and bottom and lower sidewalls of the trench, a trap structure interposed between upper sidewalls of the trench and the gate electrode and comprising a tunneling layer, a trapping layer, and a blocking layer, and source and drain regions formed on both sides of the semiconductor substrate with respect to the trench, in which the gate electrode insulating layer is not formed and partially overlapped by the trapping layer.

This application claims priority from Korean Patent Application No.10-2004-0088941 filed on Nov. 3, 2004 in the Korean Intellectual Property Office, the contents of which are incorporated herein by reference in their entirety.

### BACKGROUND OF THE INVENTION

1. Field of the Invention

The present invention relates to a nonvolatile memory device and a method of manufacturing the same. More particularly, the present invention relates to a nonvolatile memory device that has enhanced endurance and can accurately read stored data, and a method of manufacturing the same.

2. Description of the Related Art

Stacked gate type nonvolatile memory devices have been widely used in the industry. As high integration of nonvolatile memory devices rapidly proceeds, there is an extremely high demand for scaling down stacked gate type nonvolatile memory devices. However, since stacked gate type nonvolatile memory devices require a high voltage for programming or erasing, and it is difficult to produce an effective gate channel when fabricating stacked gate type nonvolatile memory devices, it is extremely difficult to further scale down the stacked gate type nonvolatile memory devices.

In this regard, various studies about new nonvolatile memory devices as substitutes for stacked gate type nonvolatile memory devices are under way. In particular, trench gate type nonvolatile memory devices have received much interest as next generation devices that can be substituted for stacked gate type nonvolatile memory devices.

Trench gate type nonvolatile memory devices are memory devices in which a trapping layer is continuously formed from a source region to a drain region along a channel region formed at an interface between a trench and a semiconductor substrate. In more detail, trench gate type nonvolatile memory devices have a structure including a trench formed between a source region and a drain region in a semiconductor substrate, a floating trap layer including a trapping layer and formed along an inner wall of the trench, and a gate electrode formed in the trench in which the floating trap layer is formed.

In trench gate type nonvolatile memory devices with the above-described structure, a channel between a source region and a drain region is formed along an interface between a semiconductor substrate and a trench. Therefore, even if the cell size of the memory devices is reduced, an effective gate channel can be sufficiently obtained.

In spite of these advantages, in common trench gate type nonvolatile memory devices, a trapping layer is formed throughout a gate channel, like in stacked gate type nonvolatile memory devices, and thus, endurance may be degraded or reading may be inaccurate.

Furthermore, diffusion of electrons into a channel after programming or drifting of electrons into a channel upon baking may occur, thereby lowering the reliability of nonvolatile memory devices.

### SUMMARY OF THE INVENTION

The present invention provides a trench gate type nonvolatile memory device that has enhanced endurance and can accurately read stored data.

The present invention also provides a method of manufacturing a trench gate type nonvolatile memory device that has enhanced endurance and can accurately read stored data.

According to an aspect of the present invention, there is provided a nonvolatile memory device including a trench formed in a semiconductor substrate; a gate electrode formed in the trench, a gate electrode insulating layer interposed between the gate electrode and bottom and lower sidewalls of the trench, a trap structure interposed between upper sidewalls of the trench and the gate electrode and including a tunneling layer, a trapping layer, and a blocking layer, and source and drain regions formed in both sides of the semiconductor substrate with respect to the trench in which the gate electrode insulating layer is not formed and partially overlapped by the trapping layer.

According to another aspect of the present invention, there is provided a nonvolatile memory device including a trench formed in a semiconductor substrate, a gate electrode formed in the trench, a gate electrode insulating layer interposed between the gate electrode and bottom and lower sidewalls of the trench, a trap structure interposed between upper sidewalls of the trench and the gate electrode and comprising a tunneling layer, a trapping layer, and a blocking layer, and source and drain regions formed in both sides of the semiconductor substrate with respect to the trench in which the gate electrode insulating layer is not formed, one of the source and drain regions being fully overlapped by the trapping layer.

According to still another aspect of the present invention, there is provided a method of manufacturing a nonvolatile memory device, including forming a trench in a semiconductor substrate; conformally forming a gate electrode insulating layer on the semiconductor substrate in which the trench is formed; partially forming a gate electrode in the trench; removing a portion of the gate electrode insulating layer formed above the partially formed gate electrode; sequentially and conformally forming a tunneling layer, a trapping layer, and a blocking layer on an upper surface of the semiconductor substrate, an upper surface of the partially formed gate electrode, and an inner surface of the trench; etching the tunneling layer, the trapping layer, and the blocking layer so that an upper surface of the semiconductor substrate and an upper surface of the partially formed gate electrode are exposed; completing a gate electrode by filling the trench; and forming source and drain regions in the semiconductor substrate so that the source and drain regions are partially overlapped by the trapping layer.

According to yet another aspect of the present invention, there is provided a method of manufacturing a nonvolatile memory device, including forming a trench in a semiconductor substrate; conformally forming a gate electrode insulating layer on the semiconductor substrate in which the trench is formed; partially forming a gate electrode in the trench; removing a portion of the gate electrode insulating layer formed above the partially formed gate electrode; sequentially and conformally forming a tunneling layer, a trapping layer, and a blocking layer on an upper surface of the semiconductor substrate, an upper surface of the partially formed gate electrode, and an inner surface of the trench; etching the tunneling layer, the trapping layer, and the blocking layer so that an upper surface of the semiconductor substrate and an upper surface of the partially formed gate electrode are exposed; completing a gate electrode by filling the trench; and forming source and drain regions in the semiconductor substrate so that one of the source and drain regions is fully overlapped by the trapping layer.

### BRIEF DESCRIPTION OF THE DRAWINGS

The foregoing and other objects, features and advantages of the invention will be apparent from the more particular description of preferred aspects of the invention, as illustrated in the accompanying drawings in which like reference characters refer to the same parts throughout the different views. The drawings are not necessarily to scale, emphasis instead being placed upon illustrating the principles of the invention. In the drawings, the thickness of layers and regions are exaggerated for clarity.

FIG. 1 is a sectional view of a nonvolatile memory device according to a first embodiment of the present invention.

FIGS. 2 through 5 are sequential sectional views that illustrate a method of manufacturing a nonvolatile memory device according to a first embodiment of the present invention.

FIG. 6 is a sectional view of a nonvolatile memory device according to a second embodiment of the present invention.

FIG. 7 is a graph illustrating endurance characteristics of a nonvolatile memory device according to embodiments of the present invention.

### DETAILED DESCRIPTION OF THE INVENTION

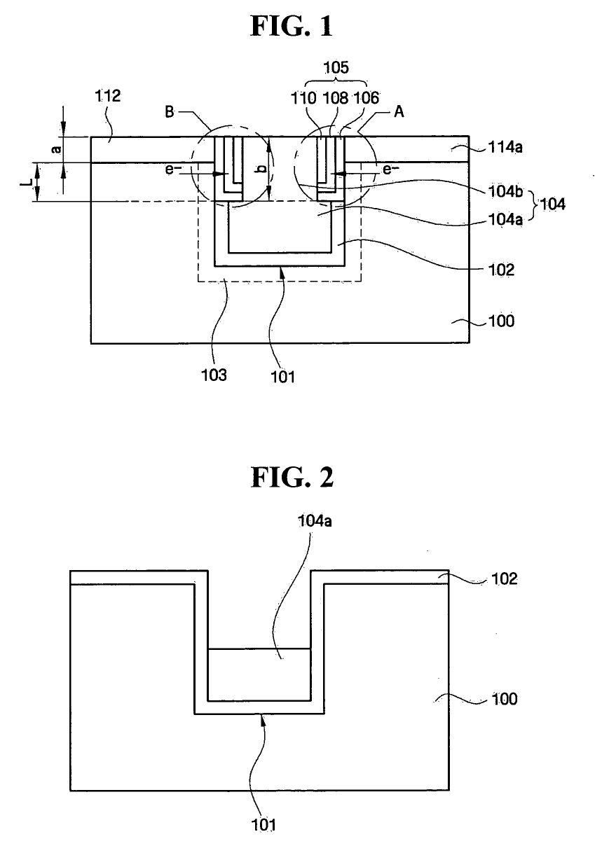

Hereinafter, a nonvolatile memory device according to a first embodiment of the present invention will be described with reference to FIG. 1.

FIG. 1 is a sectional view illustrating a unit memory cell of a nonvolatile memory device according to a first embodiment of the present invention. For convenience of illustration, the “unit memory cell” as used herein is referred to as a “nonvolatile memory device.”

Referring to FIG. 1, a trench 101 is formed to a predetermined depth in a center of a semiconductor substrate 100 for fabrication of a nonvolatile memory device. A source region 112 and a drain region 114 are formed at upper sides of the semiconductor substrate 100, with respect to the trench 101.

Here, it will be understood by those of ordinary skill in the art that a drain region may be formed in a semiconductor substrate area indicated by a reference numeral 112 and a source region may be formed in a semiconductor substrate area indicated by a reference numeral 114.

A gate electrode 104 made of a conductive material is formed in the trench 101.

A plurality of layers are formed at an interface between the gate electrode 104 and the semiconductor substrate 100 and a detailed description thereof will now be provided by dividing the gate electrode 104 into a first gate electrode 104a below a dotted line and a second gate electrode 104b above the dotted line. That is, the layers formed at an interface between the gate electrode 104 and the semiconductor substrate 100 will be described by dividing them into a “layer interposed between the first gate electrode 104a and the trench 101” and a “layer interposed between the second gate electrode 104b and the trench 101”.

First, the “layer interposed between the first gate electrode 104a and the trench 101” is a gate electrode insulating layer 102. In more detail, the gate electrode insulating layer 102 is formed on the bottom and sidewall portions of the trench 101. The gate electrode insulating layer 102 serves to insulate a channel region 103 formed in the semiconductor substrate 100 contacting the trench 101 and the first gate electrode 104a.

The “layer interposed between the second gate electrode 104b and the trench 101” is a trap structure 105 in which a tunneling layer 106, a trapping layer 108, and a blocking layer 110 are stacked.

In more detail, the tunneling layer 106, the trapping layer 108, and the blocking layer 110 are stacked on both sidewall portions of the trench 101 in such a way that the tunneling layer 106 and the trapping layer 108 are “L”-shaped sections (for those formed at a left sidewall of the trench 101) and inverted “L”-shaped sections (for those formed at a right sidewall of the trench 101) and the blocking layer 110 is an “I”-shaped section adjacent to the trapping layer 108.

Here, the trap structure 105, which is a stacked structure of the tunneling layer 106, the trapping layer 108, and the blocking layer 110, partially overlaps the channel region 103 formed in the semiconductor substrate 100, in addition to the source region 112 and the drain region 114.

The tunneling layer 106 is essentially responsible for insulation between the trapping layer 108 and the semiconductor substrate 100. However, when an appropriate voltage is applied to the source region 112, the drain region 114, and the gate electrode 104, tunneling of electrons present in the channel region 103 of the semiconductor substrate 100 through the tunneling layer 106 can be induced. That is, when energy transferred to electrons present in the channel region 103 is higher than an energy barrier formed between the semiconductor substrate 100 and the trapping layer 108, tunneling of electrons through the tunneling layer 106 can occur.

The trapping layer 108 is a storage space of a nonvolatile memory device in which information is substantially stored. In more detail, when tunneling of electrons present in the channel region 103 is induced by applying an appropriate voltage to the source region 112, the drain region 114, and the gate electrode 104, a charge trapping region (not shown) is formed in the trapping layer 108. Therefore, storage of predetermined information can be accomplished. Here, the charge trapping region formed in the trapping layer 108 changes the potential of the channel region 103. Stored information is read out by detecting the potential difference in the channel region 103 during a read operation.

The blocking layer 110 serves to insulate the trapping layer 108 and the gate electrode 104. In particular, the blocking layer 110 serves to prevent leakage of charge trapped in the trapping layer 108 into the gate electrode 104.

As described above, the nonvolatile memory device according to the first embodiment of the present invention has a structure in which the trapping layer 108 locally overlaps the channel region 103 formed at an interface between the trench 101 and the semiconductor substrate 100. This is different from the conventional structure in which a trapping layer overlaps the entire channel region formed at an interface between a trench and a semiconductor substrate.

Preferably, the length (L) of the overlapped area of the present invention is 500 Å or more.

Generally, the tunneling layer 106, the trapping layer 108, and the blocking layer 110, which are sequentially stacked in the trap structure 105, are respectively made of oxide, nitride, and oxide. However, the tunneling layer 106, the trapping layer 108, and the blocking layer 110 do not have to be respectively made of oxide, nitride, and oxide. Various materials may also be used for formation of the tunneling layer 106, the trapping layer 108, and the blocking layer 110. Furthermore, each of the tunneling layer 106, the trapping layer 108, and the blocking layer 110 constituting the trap structure 105 may also be formed as a composite layer in which a plurality of layers made of various materials are stacked. A detailed description thereof will be described later in a method of manufacturing the nonvolatile memory device.

Hereinafter, programming, reading, and erasing operations of the nonvolatile memory device according to the first embodiment of the present invention will be described in detail.

Programming, reading, and erasing operations using a right region of the gate electrode 104, i.e., a region A, will now be described. However, it will be understood by those of ordinary skill in the art that the programming, reading, and erasing operations using region A can also use a left region of the gate electrode 104, i.e., a region B.

The programming operation is performed by Hot Electron Injection (HEI). In more detail, a positive voltage, for example, a voltage of 5 to 6V is applied to the gate electrode 104.

Then, a positive voltage, for example, a voltage of 4 to 5 V is applied to the drain region 114 and a voltage lower than the voltage applied to the drain region 114, for example, a voltage of 0 to 1 V is applied to the source region 112. In this way, when a voltage is applied to a nonvolatile memory device, charges are induced in the channel region 103 at an interface between the trench 101 and the semiconductor substrate 100.

At this time, an inversion area and a depletion area are formed in the channel region 103. In the inversion area, electrons are present as carriers. The inversion area formed in the channel region 103 is not connected to the drain region 114 and it is pinched-off at an overlapped area of the channel region 103 and the trapping layer 108. Therefore, the channel region 103 between the drain region 114 and the inversion area is the depletion area.

As described above, when the channel region 103 is formed, electrons present in an end adjacent to the drain region among both ends of the inversion area are injected into the trapping layer 108 by tunneling through the tunneling layer 106. At this time, the injected electrons accumulate in the trapping layer 108, and thus, a charge trapping region (not shown) is formed. Thus, the programming operation is completed.

Here, the charge trapping region formed in the trapping layer 108 changes the potential of the channel region 103. Stored information is read out by detecting the potential difference in the channel region 103 during a read operation.

A read operation can be performed by applying a positive voltage, for example a voltage of 1.8-3.6 V to the gate electrode 104, grounding the drain region 114, and applying a positive voltage, for example, a voltage of 0.5-1.6V to the source region 112.

As described above, the charge trapping region formed in the trapping layer 108 during the programming operation changes the potential of the channel region 103. In this regard, detection of a potential difference during a read operation allows for reading of stored information.

Here, electrons trapped in the trapping layer 108 are prevented from leaking into the gate electrode 104 by the blocking layer 110.

The erase operation is performed by Hot Hole Injection (HHI). In more detail, first, a negative voltage, for example a voltage of −5 to −9 V is applied to the gate electrode 104. Then, a positive voltage, for example a voltage of 5 to 7 V is applied to the source region 112 and the drain region 114.

As a result, holes are injected into the trapping layer 108 and then combine with electrons trapped in the charge trapping region of the trapping layer 108. Thus the erase operation is complete.

Here, when a voltage is applied to the gate electrode 104, the source region 112, and the drain region 114 as described above, and a negative voltage, for example a voltage of −1.0 to −1.5 V is further applied to the semiconductor substrate 100, the erase speed can be increased.

Hitherto, programming, reading, and erasing operations of a nonvolatile memory device using only region A have been described. In this regard, it will be understood by those of ordinary skill in the art that the nonvolatile memory device according to the first embodiment of the present invention can store 2 bits of information by using regions A and B.

Furthermore, during a programming operation, when the amount of charge generated by electron injection into the trapping layer 108 can be adjusted by controlling the programming time, more than 2 bits of information can be stored.

For example, when three-level voltages, for example, 0V, 0-2V, and 2-4V are created by adjusting the amount of charge generated in the trapping layer 108, 2 bits of information can be stored using only region A.

Of course, such a charge adjustment method can be applied to region B. In this regard, simultaneous use of the regions A and B will enable 4 bits of information to be stored. Therefore, the memory density can be increased without increasing the cell area.

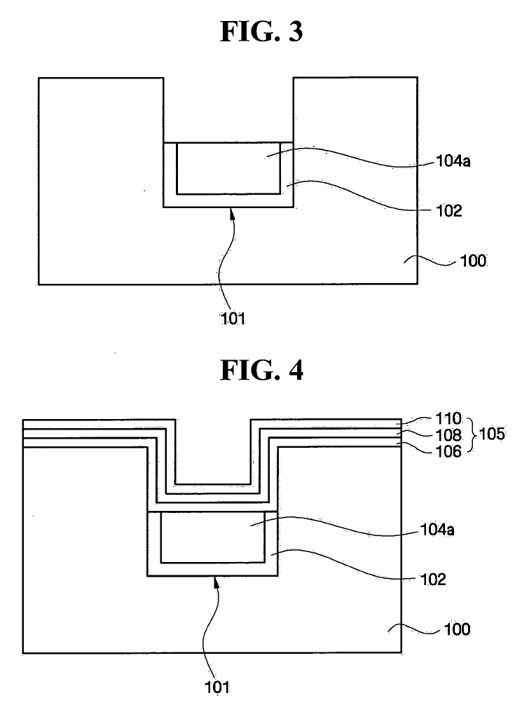

Hereinafter, a method of manufacturing a nonvolatile memory device according to a first embodiment of the present invention will be described with reference to FIGS. 2 through 5.

FIGS. 2 through 5 are sequential sectional views that illustrate the method of manufacturing the nonvolatile memory device according to the first embodiment of the present invention.

First, referring to FIG. 2, photoresist is coated on a semiconductor substrate 100 that has been washed with distilled water. Next, a semiconductor substrate portion, which is used to form a trench 101, is exposed and developed. Then, the semiconductor substrate 100 is etched to a predetermined depth using plasma ion etching to form a trench 101.

When the trench 101 is formed in the semiconductor substrate 100, oxide is conformally deposited on the surfaces of the semiconductor substrate 100 and the trench 101 using Low Pressure Chemical Vapor Deposition (LPCVD) or Plasma Enhanced Chemical Vapor Deposition (PECVD) to form an oxide film as a gate electrode insulating layer 102. The gate electrode insulating layer 102 may also be an oxide film formed by N₂O annealing of a Middle Temperature Oxide (MTO) film.

The gate electrode insulating layer 102 is formed to a thickness sufficient to insulate a first gate electrode 104a to be formed in the trench 101 and the semiconductor substrate 100, for example, it can be formed to a thickness of 50 to 100 Å.

Next, the trench 101 is partially filled with a conductive material such as polysilicon to form the first gate electrode 104a. For this, first, polysilicon is deposited on the entire surface of the semiconductor substrate 100. Then, polishing is performed by a Chemical Mechanical Polishing (CMP) process until the gate electrode insulating layer 102 formed on the semiconductor substrate 100 is exposed. At this time, an etch-back process may also be used instead of the CMP process. Then, polysilicon filled in the trench 101 is partially removed by wet etching to form the first gate electrode 104a.

Here, since the thickness of the first gate electrode 104a affects the longitudinal length of a trapping layer (see 108 of FIG. 1) to be formed on the first gate electrode 104a, polysilicon must be etched considering a desired longitudinal length of the trapping layer.

Alternatively, the formation of the first gate electrode 104a in the trench 101 may also be performed by directly filling polysilicon to a desired depth in the trench 101 without etching and/or polishing.

Next, the oxide film or the gate electrode insulating layer 102 exposed on the surface of the semiconductor substrate 100 and the sidewalls of the trench 101 is removed by wet etching, as shown in FIG. 3.

FIG. 3 illustrates the structure in which the oxide film or the gate electrode insulating layer 102 exposed on the surface of the semiconductor substrate 100 and the sidewalls of the trench 101 is removed by wet etching.

As described above, when an exposed portion of the oxide film or the gate electrode insulating layer 102 is removed, the gate electrode insulating layer 102 remains only at an interface between the first gate electrode 1 04a and the trench 101.

Next, a tunneling layer 106, a trapping layer 108, and a blocking layer 110 are sequentially conformally deposited on the entire surface of the semiconductor substrate 100, as shown in FIG. 4.

FIG. 4 illustrates a trap structure 105 formed by sequentially depositing the tunneling layer 106, the trapping layer 108, and the blocking layer 110 on the entire surface of the semiconductor substrate 100.

Here, the tunneling layer 106 is generally made of oxide. Alternatively, the tunneling layer 106 may also be made of a material other than oxide to enhance programming efficiency.

For example, the tunneling layer 106 may be a nitride layer, an oxinitride layer, a high-k material layer, or a combination of the foregoing layers.

Here, the high-k material may be aluminum (Al) oxide, zirconium (Zr) oxide, hafnium (Hf) oxide, lanthanum (La) oxide, or a combination thereof.

Here, the tunneling layer 106 is formed to such a thickness, for example, 20 to 60 Å, that electrons present in an inversion area of a channel region (see 103 of FIG. 1) formed at an interface between the semiconductor substrate 100 and the trench 101 are allowed to undergo tunneling events.

The trapping layer 108 is generally made of nitride. Alternatively, the trapping layer 108 may also be made of a material other than nitride to enhance the programming and erasing efficiency.

For example, the trapping layer 108 may be a single layer made of a high-k material such as aluminum (Al) oxide, zirconium (Zr) oxide, hafnium (Hf) oxide, or lanthanum (La) oxide, or a combination of these layers.

The trapping layer 108 may also be a combination of: a single layer made of a high-k material such as aluminum (Al) oxide, zirconium (Zr) oxide, hafnium (Hf) oxide, or lanthanum (La) oxide, or a combination of these layers, and a nitride layer.

The trapping layer 108 may also be a combination of: a single layer made of a high-k material such as aluminum (Al) oxide, zirconium (Zr) oxide, hafnium (Hf) oxide, or lanthanum (La) oxide, or a combination of these layers, a nitride layer, and a nanocrystal layer.

The trapping layer 108 may also be a single layer made of aluminum (Al) oxide, zirconium (Zr) oxide, hafnium (Hf) oxide, lanthanum (La) oxide, oxinitride, silicon dioxide (SiO₂), or a combination of these layers.

In addition, the trapping layer 108 may also be a single layer made of nanocrystal, nitride dot, nano-conducting dot, silicon nitride, boron nitride, a high-k material, or a combination of these layers.

In this way, when the trapping layer 108 is formed as a multi-layer, an interlayer interface can serve as a bulk-trap site, which provides more space to store more electrons during programming.

Here, the trapping layer 108 is formed to a thickness appropriate for trapping charges, for example, a thickness of 40 to 80 Å.

The blocking layer 110 is generally made of oxide. Alternatively, the blocking layer 110 may also be made of a material other than oxide to enhance the charge blocking capability and the bake retention capability.

For example, the blocking layer 110 may be a multi-layer formed by sequentially stacking a thermal oxide layer, a silicon oxinitride (SiON) layer, an MTO layer, a silicon oxinitride layer, and an N₂O annealed MTO layer.

The blocking layer 110 may also be a single layer made of a high-k material such as aluminum (Al) oxide, zirconium (Zr) oxide, hafnium (Hf) oxide, or lanthanum (La) oxide, or a combination of these layers.

Here, the blocking layer 110 is formed to a thickness appropriate to block charges generated in the trapping layer 108, for example, a thickness of 80 to 120 Å.

Next, etching is performed over the entire surface of the semiconductor substrate 100 by an isotropic etching process similar to a spacer etching process, as shown in FIG. 5. The isotropic etching is performed until an upper surface of the semiconductor substrate 100 is exposed.

FIG. 5 illustrates the structure after isotropic etching is performed over the entire surface of the semiconductor substrate 100. As described above, when the upper surface of the semiconductor substrate 100 is exposed, an upper surface of the first gate electrode 104a is also exposed. As a result, the trap structure 105 composed of the tunneling layer 106, the trapping layer 108, and the blocking layer 110 remains only on the upper sidewalls of the trench 101 above the first gate electrode 104a (see the regions A and B of FIG. 1).

Here, the trap structure 105 stacked on the upper sidewalls of the trench 101 is used as a memory storage space of a nonvolatile memory device. Information is substantially stored in the trapping layer 108.

The trapping layer 108 formed on the upper sidewalls of the trench 101 must be formed considering the depths of a source region (see 112 of FIG. 1) and a drain region (see 114 of FIG. 1) to be formed in upper areas of the semiconductor substrate 100 in a subsequent process.

If the longitudinal length (see b of FIG. 1) of the trapping layer 108 is shorter than the depth (see a of FIG. 1) of the source region and the drain region, tunneling of electrons present in the inversion area of a channel region (see 103 of FIG. 1) into the trapping layer 108 through the tunneling layer 106 is blocked, and the nonvolatile memory device cannot perform its desired operation.

Specifically, assuming that the depth of the source region 112 and the drain region 114 is a and the longitudinal length of the trapping layer 108 is b, it is preferable that b is 1.4 to 2 times a, and the length L of the overlapped area of the trapping layer 108 and the semiconductor substrate 100 is at least 500 Å (see FIG. 1).

For example, when the source region 112 and the drain region 114 are generally formed to a depth of 700 Å, b may be set to 1,200 Å so that L is 500 Å. Here, as described above, the longitudinal length of the trapping layer 108 can be adjusted by varying the depth of the first gate electrode 104a.

Subsequently, polysilicon is deposited on the semiconductor substrate 100 and a CMP process is performed until an upper surface of the semiconductor substrate 100 is exposed, to thereby form a second gate electrode (see 104b of FIG. 1). When the second gate electrode is formed, the trench 101 is fully filled with polysilicon. This completes a gate electrode (see 104 of FIG. 1) composed of the first gate electrode 104a and the second gate electrode 104b.

Then, ion impurities with opposite polarity to that of the semiconductor substrate 100 are implanted into exposed areas of the semiconductor substrate 100 to form a source region (see 112 of FIG. 1) and a drain region (see 114 of FIG. 1). At this time, phosphorus (P), arsenic (As), and others may be used as the ion impurities.

Through the above-described procedures, a nonvolatile memory device as shown in FIG. 1 is produced.

Hitherto, a method of manufacturing the nonvolatile memory device according to the first embodiment of the present invention has been described. In addition to the above-described processes, several processes for enhancing the electrical properties of the nonvolatile memory device may be further performed.

First, to increase the programming and erasing efficiency, a halo ion injection region may be formed prior to forming the source region 112 and the drain region 114. The halo ion injection region can be formed by pocket implantation of ions of boron, indium, silicon, germanium, and others into regions beneath the source region 112 and the drain region 114 within a tilt range of 0 to 45 degrees.

The halo ion injection region is formed as an abrupt or step junction (not shown) at a junction with the trapping layer 108 and a bulk overlapped with the gate electrode 104.

Here, a halo ion injection process serves to prevent horizontal approximation of depletion areas of the source region 112 and the drain region 114 without affecting the doping concentration of a channel region (see 103 of FIG. 1) that determines the threshold voltage of the transistor. That is, the halo ion injection process is used to prevent a short channel effect. Generally, the halo ion injection process is involved in fabrication of a semiconductor device with an LDD (Lightly Doped Drain) structure.

The nonvolatile memory device according to the first embodiment of the present invention is a trench gate type nonvolatile memory device. Therefore, an effective channel length is easily ensured. Further, addition of a halo ion injection region to the nonvolatile memory device according to the first embodiment of the present invention can additionally increase device stability, thereby enhancing the programming and erasing efficiency.

Furthermore, when the critical voltage of the channel region 103 overlapping the trap structure 105 in the semiconductor substrate 100 is lowered, device endurance is enhanced and a disturbance phenomenon in the device can be reduced. For this, before or after forming the gate electrode insulating layer 102, low energy ion implantation into only a portion corresponding to a surface of the channel region 103 can be performed. At this time, ions with the same polarity as the channel region 103 to be formed are implanted.

In addition, to improve both conformality and the dangling bond between the tunneling layer 106 and the semiconductor substrate 100, nitrogen may be implanted between the tunneling layer 106 and the semiconductor substrate 100 by Decoupled Plasma Nitridation or ion implantation. This procedure may also be performed between the gate electrode 104 and the semiconductor substrate 100.

The above-described additional processes may also be applied to a nonvolatile memory device according to a second embodiment of the present invention and a method of manufacturing the same as will be described below.

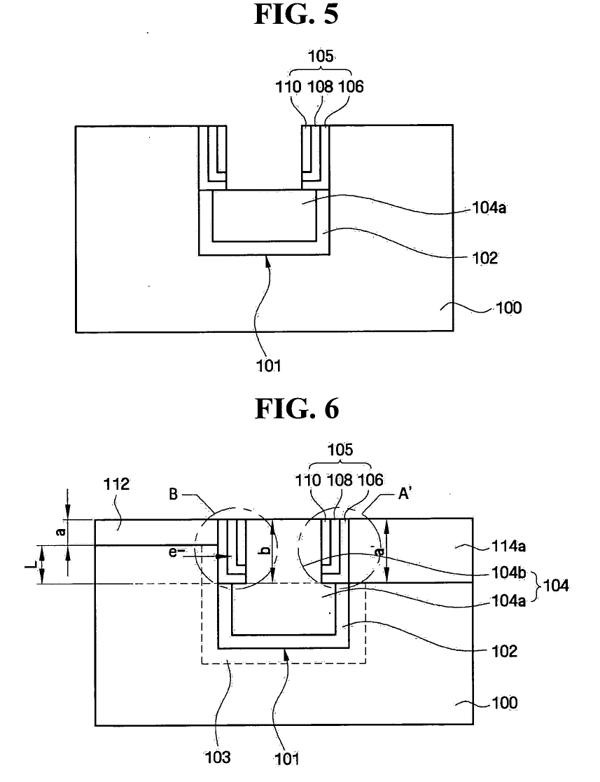

Hereinafter, the nonvolatile memory device according to the second embodiment of the present invention will be described with reference to FIG. 6.

FIG. 6 is a sectional view illustrating a unit memory cell of the nonvolatile memory device according to the second embodiment of the present invention. For convenience of illustration, the “unit memory cell” as used herein is referred to as a “nonvolatile memory device.”

The nonvolatile memory device according to the second embodiment of the present invention has almost the same structure as that according to the first embodiment of the present invention except for the details given below, and thus, the above description about the first embodiment is correspondingly applied to the second embodiment.

Referring to FIG. 6, the nonvolatile memory device according to the second embodiment of the present invention has the same structure as that according to the first embodiment of the present invention except the depth of a drain region 114a.

In the nonvolatile memory device according to the second embodiment of the present invention, the depth of the drain region 114a is equal to or larger than the longitudinal length of the trap structure 105 formed by sequentially stacking the tunneling layer 106, the trapping layer 108, and the blocking layer 110 on a right sidewall of the trench 101 (see region A′).

In this structure, the drain region 114a is fully overlapped by the trapping layer 108. Therefore, when an inversion area of the channel region 103 is formed, tunneling of electrons present in the inversion area into the trapping layer 108 through the tunneling layer 106 is blocked.

The depth of the source region 112 may also be equal to or greater than the longitudinal length of the trap structure 10 so that the source region 112 is fully overlapped by the trapping layer 108.

In this regard, the nonvolatile memory device according to the second embodiment of the present invention is useful when the trap structure 105 formed by sequentially stacking the tunneling layer 106, the trapping layer 108, and the blocking layer 110 on only one sidewall of the trench 101 is required.

Hereinafter, a method of manufacturing a nonvolatile memory device according to a second embodiment of the present invention will be described.

The method of manufacturing the nonvolatile memory device according to the second embodiment of the present invention is almost the same as that according to the first embodiment described with reference to FIGS. 2 through 5 except for the details given below, and thus, the above description about the first embodiment is correspondingly applied to the second embodiment.

With respect to the operations shown in FIGS. 2 through 5, the method of manufacturing the nonvolatile memory device according to the second embodiment of the present invention is the same as that according to the first embodiment. However, the method of manufacturing the nonvolatile memory device according to the second embodiment of the present invention is different from that according to the first embodiment in that the drain region 114a is formed to be fully overlapped by the trapping layer 108.

Formation of the source region 112 and the drain region 114a will now be described in detail.

First, when the gate electrode 104 is completed as shown in FIG. 5, the trap structure 105 composed of the tunneling layer 106, the trapping layer 108, and the blocking layer 110 remains only on the upper sidewalls of the trench 101 above the first gate electrode 104a (see the regions A and B of FIG. 1) and upper surfaces of the semiconductor substrate 100 and the gate electrode 104 are exposed.

Next, the source region 112 and the drain region 114a are formed so that the drain region 114a is fully overlapped by the trapping layer 108.

To this end, only a portion as the source region 112 is exposed by a photoresist process. Then, the source region 112 is formed to a predetermined depth. At this time, the depth a of the source region 112 is formed to be smaller than the longitudinal length b of the trapping layer 108.

Next, a select area (a region ‘A’) intended for the drain region 114a is exposed by a photoresist process. Then, the drain region 114a is formed to a predetermined depth. At this time, the depth a′ of the drain region 114a is formed to be larger than the longitudinal length b of the trapping layer 108. Therefore, the drain region 114a is fully overlapped by the trapping layer 108, and thus, the trap structure 105 formed in the region A′ cannot be utilized.

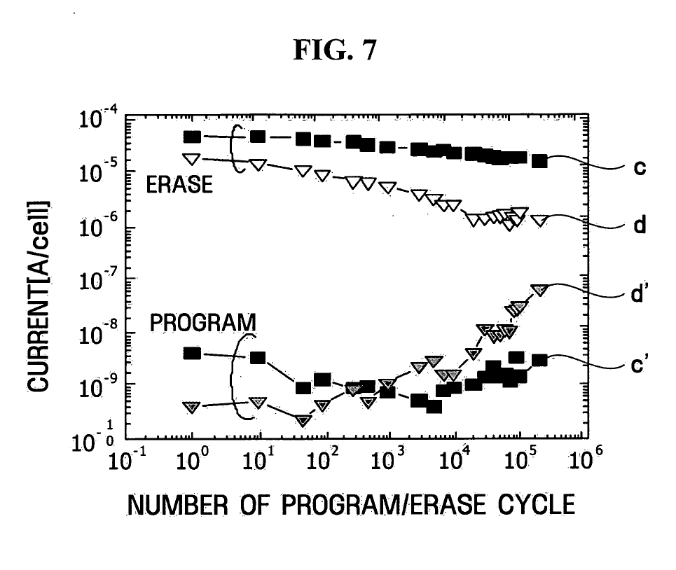

Hereinafter, structural advantages of trench gate type nonvolatile memory devices in which a trapping layer is locally formed, like in the embodiments of the present invention, will be described with reference to FIG. 7.

FIG. 7 is a test result graph illustrating the endurance characteristics of a trench gate type nonvolatile memory device of the present invention in which a trapping layer is locally formed along a channel region formed at an interface between a trench and a semiconductor substrate (see FIGS. 1 and 6) and a common trench gate type nonvolatile memory device in which a trapping layer is continuously formed along a channel region formed at an interface between a trench and a semiconductor substrate.

Prior to interpretation of the test result graph of FIG. 7, the meaning of the term “endurance” as used in the memory device field will be described. The phrase “endurance of a memory device” indicates a resistance to degradation in electrical properties of a memory device during the repetition of programming and erasing operations. The endurance of a memory device can be evaluated by measuring the current change in a charge trapping layer per memory cell with respect to the number of programming and erasing operations.

In the graph of FIG. 7, the x-axis represents the number of program/erase cycles and the y-axis represents the current of the trapping layer per unit memory cell (A/cell). Curves c, c′, d, and d′ are grouped into programming and erasing operations. The upper two curves c and d are the erase operation and the lower two curves c′ and d′ are the programming operation. The endurance test result graphs c and c′ for the trench gate type nonvolatile memory device of the present invention are represented by squares (▪, □), whereas the endurance test result graphs d and d′ for the common trench gate type nonvolatile memory device are represented by triangles (▾, ∇).

Referring to FIG. 7, as the number of program/erase cycles increases, the current change of the curves represented by squares is smaller than that of the curves represented by triangles. This suggests that endurance of the trench gate type nonvolatile memory device of the present invention is better than that of the common trench gate type nonvolatile memory device.

Generally, in a memory device, as the number of program/erase cycles increases, a change in the current of a trapping layer is caused by lateral diffusion of electrons in the trapping layer or inflow of the electrons into the channel through a tunneling layer. Since the endurance of the trench gate type nonvolatile memory device of the present invention is better than that of the common trench gate type nonvolatile memory device, even though the number of program/erase cycles increases, the change in the current of the trapping layer of the trench gate type nonvolatile memory device of the present invention is smaller than that of the common trench gate type nonvolatile memory device.

In addition, in a memory device, hole mobility is higher in a nitride film than in an oxide film. Therefore, a critical erasing voltage is increased by lateral migration of residual holes after hot hole erasing. This phenomenon occurs less frequently in the trench gate type nonvolatile memory device of the present invention compared to a common nonvolatile memory device.

Use of a nonvolatile memory device of the present invention and a fabrication method thereof provides at least the following advantages.

First, a short channel effect can be reduced.

Second, an elevation phenomenon of a critical erasing voltage by lateral migration of residual holes after hot hole erasing can be reduced.

Third, changes in the current of a trapping layer with respect to the number of program/erase cycles are reduced.

Fourth, the critical voltage of the channel is reduced, and thus, device endurance is enhanced and a disturbance phenomenon in the device can be reduced.

Fifth, conformality and the dangling bond between a tunneling layer and a semiconductor substrate can be improved.

While the present invention has been particularly shown and described with reference to exemplary embodiments thereof, it will be understood by those of ordinary skill in the art that various changes in form and details may be made therein without departing from the spirit and scope of the present invention as defined by the following claims.

1. A nonvolatile memory device comprising:.
a trench formed in a semiconductor substrate;
a gate electrode formed in the trench;
a gate electrode insulating layer interposed between the gate electrode and bottom and lower sidewalls of the trench;
a trap structure interposed between upper sidewalls of the trench and the gate electrode and comprising a tunneling layer, a trapping layer, and a blocking layer; and
source and drain regions formed on both sides of the semiconductor substrate with respect to the trench, in which the gate electrode insulating layer is not formed and which is partially overlapped by the trapping layer.

2. A nonvolatile memory device comprising:
a trench formed in a semiconductor substrate;
a gate electrode formed in the trench;
a gate electrode insulating layer interposed between the gate electrode and bottom and lower sidewalls of the trench;
a trap structure interposed between upper sidewalls of the trench and the gate electrode and comprising a tunneling layer, a trapping layer, and a blocking layer; and
source and drain regions formed on both sides of the semiconductor substrate with respect to the trench, in which the gate electrode insulating layer is not formed, one of the source and drain regions being fully overlapped by the trapping layer.

3. The nonvolatile memory device of claim 2, further comprising a halo ion injection region formed as an abrupt or step junction beneath the source and drain regions.

4. The nonvolatile memory device of claim 2, further comprising an ion implantation region on a surface of a channel formed at an interface between the trench and the semiconductor substrate.

5. The nonvolatile memory device of claim 2, further comprising a nitrogen ion implantation region between the tunneling layer and the semiconductor substrate.

6. The nonvolatile memory device of claim 2, further comprising a nitrogen ion implantation region between the gate electrode and the semiconductor substrate.

7. (canceled)

8. The nonvolatile memory device of claim 2, wherein the tunneling layer is one of an oxide layer, a nitride layer, an oxinitride layer, a high-k material layer, and a combination of the foregoing layers.

9. (canceled)

10. (canceled)

11. (canceled)

13. (canceled)

14. The nonvolatile memory device of claim 2, wherein the trapping layer is one of a nitride layer, a high-k material layer, an oxinitride layer, a silicon dioxide (SiO₂) layer, and a combination of the foregoing layers.

15. (canceled)

16. The nonvolatile memory device of claim 2, wherein the trapping layer is one of a nitride dot layer, a nanocrystal layer, a nano-conducting dot layer, and a combination of the foregoing layers.

17. The nonvolatile memory device of claim 2, wherein the blocking layer is a composite layer composed of a thermal oxide layer, a silicon oxinitride layer, an MTO layer, a silicon oxinitride layer, and an annealed MTO layer.

18. The nonvolatile memory device of claim 2, wherein the blocking layer is one of a single layer made of a high-k material and a combination layer of at least one high-k material.

19. (canceled)

20. (canceled)

21. (canceled)

22. (canceled)

23. A method of manufacturing a nonvolatile memory device, comprising: forming a trench in a semiconductor substrate;
conformally forming a gate electrode insulating layer on the semiconductor substrate in which the trench is formed;
partially forming a gate electrode in the trench;
removing a portion of the gate electrode insulating layer formed above the partially formed gate electrode;
sequentially and conformally forming a tunneling layer, a trapping layer, and a blocking layer on an upper surface of the semiconductor substrate, an upper surface of the partially formed gate electrode, and an inner surface of the trench;
etching the tunneling layer, the trapping layer, and the blocking layer so that an upper surface of the semiconductor substrate and an upper surface of the partially formed gate electrode are exposed;
completing a gate electrode by filling the trench; and
forming source and drain regions in the semiconductor substrate so that the source and drain regions are partially overlapped by the trapping layer.

24. A method of manufacturing a nonvolatile memory device, comprising:
forming a trench in a semiconductor substrate;
conformally forming a gate electrode insulating layer on the semiconductor substrate in which the trench is formed;
partially forming a gate electrode in the trench; removing a portion of the gate electrode insulating layer formed above the partially formed gate electrode;
sequentially and conformally forming a tunneling layer, a trapping layer, and a blocking layer on an upper surface of the semiconductor substrate, an upper surface of the partially formed gate electrode, and an inner surface of the trench;
etching the tunneling layer, the trapping layer, and the blocking layer so that an upper surface of the semiconductor substrate and an upper surface of the partially formed gate electrode are exposed;
completing a gate electrode by filling the trench; and
forming source and drain regions in the semiconductor substrate so that one of the source and drain regions is fully overlapped by the trapping layer.

25. (canceled)

26. (canceled)

27. (canceled)

28. (canceled)

29. (canceled)

30. (canceled)

31. (canceled)

32. (canceled)

33. (canceled)

34. (canceled)

35. (canceled)

36. (canceled)

37. (canceled)

38. (canceled)

39. (canceled)

40. (canceled)

41. (canceled)

42. (canceled)

43. (canceled)

44. (canceled)

45. The nonvolatile memory device of claim 1, further comprising a halo ion injection region formed as an abrupt or step junction beneath the source and drain regions.

46. The nonvolatile memory device of claim 1, further comprising an ion implantation region on a surface of a channel formed at an interface between the trench and the semiconductor substrate.

47. The nonvolatile memory device of claim 1, further comprising a nitrogen ion implantation region between the tunneling layer and the semiconductor substrate.

48. The nonvolatile memory device of claim 1, further comprising a nitrogen ion implantation region between the gate electrode and the semiconductor substrate.

49. The nonvolatile memory device of claim 1, wherein the tunneling layer is one of an oxide layer, a nitride layer, an oxinitride layer, a high-k material layer, and a combination of the foregoing layers.

50. The nonvolatile memory device of claim 1, wherein the trapping layer is a combination of one or more high-k material layers, and one or more nitride or nanocrystal layers.

51. The nonvolatile memory device of claim 1, wherein the trapping layer is one of a nitride layer, a high-k material layer, an oxinitride layer, a silicon dioxide (SiO₂) layer, and a combination of the foregoing layers.

52. The nonvolatile memory device of claim 1, wherein the trapping layer is one of a nitride dot layer, a nanocrystal layer, a nano-conducting dot layer, and a combination of the foregoing layers.

53. The nonvolatile memory device of claim 1, wherein the blocking layer is a composite layer composed of a thermal oxide layer, a silicon oxinitride layer, an MTO layer, a silicon oxinitride layer, and an annealed MTO layer.

54. The nonvolatile memory device of claim 1, wherein the blocking layer is one of a single layer made of a high-k material and a combination layer of at least one high-k material.
